(19) United States
(12) Patent Application Publication
(10) Pub. No.: US 2007/0086604 A1
(43) Pub. Date: Apr. 19, 2007

(54) Constant sound level

(75) Inventor: Fabien M.J. Guillorit, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONIC, N.V., EINDHOVEN (NL)

(21) Appl. No.: 10/596,130

(22) PCT Filed: Nov. 30, 2004
(86) PCT No.: PCT/IB04/52610

§ 371 Date: Jun. 1, 2006

Related U.S. Application Data
(60) Provisional application No. 60/526,288, filed on Dec. 2, 2003.

(51) Int. Cl. H03G 3/00

(52) U.S. Cl. 381/107; 381/104

(57) ABSTRACT

A receiver or playback device (100) with an audio output includes an automatic volume control system (200) which has a controller (230) configured to output a control signal (235) to change levels of an input signal; and an adjustor (240) which changes levels of the input signal to form an adjusted signal (245) in response to the control signal (235). The controller (230) forms the control signal (235) in response to input signal, the adjusted signal and a reference signal (225). The adjustor (240) lowers the input signal and/or limits its high levels to form the adjusted signal when levels of the input signal and/or the adjusted signal exceed the reference signal (225). Additionally, the adjustor (240) increases the input signal and/or increases its low levels when levels of the input signal and/or the adjusted signal are below another reference signal (260).

The present invention relates generally to signal processing systems and methods to keep constant level of signals, and more particularly, to volume control or level adjusting systems for keeping constant sound levels within a particular television program or the like.

When watching television programs, DVDs (digital video disks) or videotapes, or listening to radio broadcasts or recorded music, the volume or levels of sound seem to change, i.e., increase or decrease, with the intensity or sharpness of the sound. The user must manually change, i.e., decrease or increase, the volume to maintain a constant sound level. For example, when a user is listening to music or watching a program at night, and there is a period of time when the music intensity increases, or a scene with loud sound levels such as explosions, shooting, car chases, yelling or screaming, it is desired to attenuate such higher sound levels to prevent awakening or disturbing other members of the household.

One conventional system for maintaining a constant sound level is described in U.S. Pat. No. 5,822,018, which is incorporated herein by reference in its entirety. This conventional system deals with sound level differences between program segments and commercial segments at the broadcast station, to ensure that the program and the commercial are broadcast with the same sound level. U.S. Pat. No. 5,046,107, which is incorporated herein by reference in its entirety, deals with maintaining constant sound when changing input sources by pre-storing input level offsets in memory associated with each input source. UK Patent Application GB 2 271 030 A, which is incorporated herein by reference in its entirety, describes an electronic control system that uses feedback to control volume in spite of signal variations introduced by external sources, such as channel changing or interference.

Such conventional systems do not provide an audio level adjustment at the receiver or playback unit used by the user that is versatile and quickly responds to volume changes and maintain volume at a constant level more precisely by adjusting the sound level within the same program, such as high sound levels of action scenes. Accordingly, there is a need for automatic level control at a consumer electronic device, such as a receiver or playback unit, to keep constant sound levels during the same program that is more versatile, responsive and accurate.

According to one embodiment of the invention, a device such as a receiver or playback device with an audio output includes an automatic volume control system which comprises a controller configured to output a control signal to change levels of an input signal; and an adjustor which changes levels of the input signal to form an adjusted signal in response to the control signal. The controller forms the control signal in response to the input signal, the adjusted signal and a reference signal. The adjustor lowers the input signal and/or limits its high levels to form the adjusted signal when levels of the input signal and/or the adjusted signal exceed the reference signal. In another embodiment, the adjustor also increases the input signal and/or increases its low levels when levels of the input signal and/or the adjusted signal are below another reference signal.

The volume or sound level of the input and adjusted signals are continuously monitored and compared to the reference signal(s) and automatically and continuously adjusted in response to the comparison results. This is in contrast to conventional systems for adjusting volume based on the signal after amplification at the intermediate frequency (IF) level as described in GB 2 271 030 A, or for adjusting the loudness of a commercial to match the loudness of a program performed at the broadcast end, as described in U.S. Pat. No. 5,822,018, where the loudness of the program is stored before a pre-roll trigger that indicates a commercial will be inserted soon. Thus, sound levels within the same program are adjusted and kept constant continuously and automatically by monitoring both the signal and the adjusted signal as will be described.

These and other features, aspects, and advantages of the apparatus and methods of the present invention will become better understood with regard to the following description, appended claims, and accompanying drawings where:

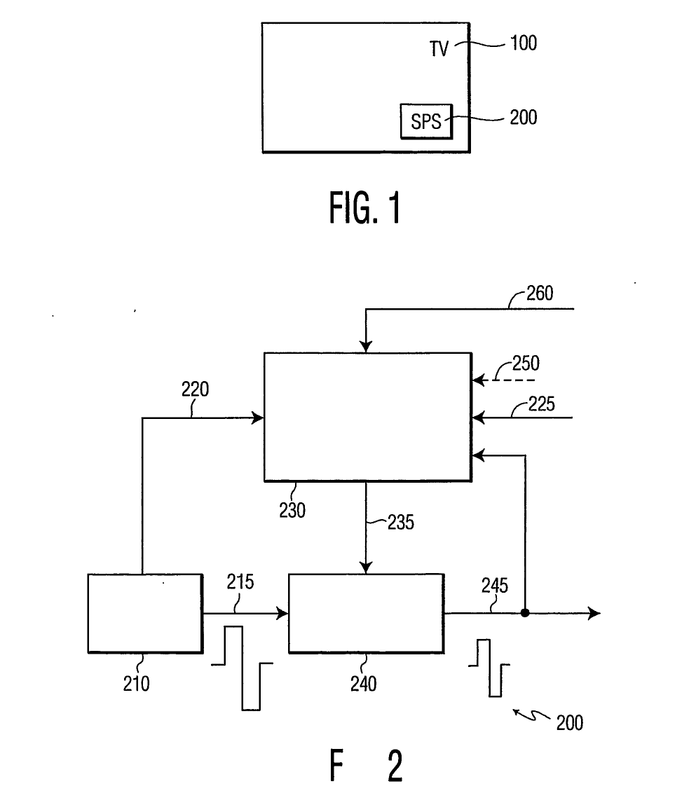

FIG. 1 shows an electronic device, such as a television, including a signal processing system for automatic volume control according to the present invention; and

FIG. 2 shows the automatic volume control shown in FIG. 1 in greater detail according to the present invention.

Although this invention is applicable to numerous and various types of electronic devices having at least an audio output, without limiting the applicability of the invention, it will be described in the context of watching television programs.

Referring now to FIG. 1, there is shown a television 100 including a signal processing system for automatic volume control 200. The signal processing system 200 receives a reference level set by a user of the television to maintain the level sound output at or below a high reference level and/or above a low reference level. The user may set the reference level(s) in the configuration panel of the television using a remote controller for example, and may change the reference level(s) or turn on/off the signal processing system 200 as desired. The remote controller of the television may have a dedicated button(s) to set or control the constant sound feature, i.e., to turn on/off the signal processing system 200 or change the reference level(s), including the high and/or low reference signals 225, 250, as will be described in conjunction with FIG. 2, which are levels of sound set by the user or measured by a detector when being set by the user, or when the user turns on a controller 230 thus activating the signal processing system 200.

Illustratively, when an action scene has loud sound levels, such as explosion, shooting, car chases, screaming or the like, where the sound level exceeds the reference level, then the signal processing system 200 lowers the volume level, such as by limiting the high level or lowering the volume, to maintain the volume constant at or below the reference level. In lieu of or in addition to this reference level, also referred to as the high reference level, the user may also set a low reference level. If the sound level falls below the low reference level, then the sound level is adjusted by increasing the volume or the low levels to maintain constant the sound level at or above the low reference level. Thus, the user can set only the high or low reference level, so that the volume is decreased when the sound level is above the high reference level, or increased when the sound level is below the low reference level. Alternatively, the user can set both the high and low reference levels so that the volume is adjusted accordingly when the sound level is either above or below the high and low reference levels, respectively.

As shown in FIG. 2, the signal processing system for automatic volume control 200 comprises a signal source 210 which outputs a signal that includes a digital form of an audio signal 215 for example, for conversion to analog, amplification and routing to a speaker. For example, the signal source 210 may be a decoder that decodes signals received from a broadcast or a recorded source. The level or intensity of sound of the audio signal 215 is measured at the signal source 210 and an intensity signal 220 provided to a sound level adjuster or controller 230 which is configured to compare the input sound level or intensity signal 220 with a high reference level 225, set by the user of the television 100. In response to the comparison, the controller 230 outputs a control signal 235 to a volume adjustor 240 for changing the audio levels of the input signal 215. In response to the control signal 235, the volume adjustor 240 adjusts the audio level of the input signal 215 and outputs an adjusted audio signal 245. In addition or alternatively, the volume adjustor 240 limits or attenuates the high levels of the audio signal. The adjusted signal 245 is eventually provided to a speaker, such as after conversion to an analog signal and amplification. The volume adjustor 240 may additionally or alternatively provide control signals to controls attenuators and/or the gain of an audio amplifier, for example. In one embodiment, instead of changing attenuation or gain levels, the volume adjustor 240 adjusts the audio signal 215, e.g., attenuated the audio signal and/or limits the high levels, to form the adjusted signal 245 which is then converted to an analog signal, amplified and provided to the speaker.

The adjusted signal 245 is also measured and fed back to the controller 230 for comparison of its audio level with the user setting or reference level 225. Thus, the controller 230 forms the control signal 235 in response to the input signal 215 or its intensity level 220, the adjusted signal 245 and the reference signal 225, such as by comparing both the input signal 215, 220 and the adjusted signal 245 with the reference signal 225. Comparing the input signal with the reference signal anticipates the audio level of the output or adjusted signal, and may be thought of as coarse tuning, while comparing the output or adjusted signal with the reference signal double checks and fine tunes the level of the signal to be amplified and heard by the user, or fine tunes the attenuation or gain level of attenuators or amplifier used to output the adjusted signal to the speaker, for example. Further, comparing the input signal with the reference signal improves responsiveness and accuracy of the volume adjustment.

The adjustor 240 lowers the input signal and/or limits its high levels to form the adjusted signal 245 when levels of the input signal and/or the adjusted signal exceed the high reference signal 225. Alternatively or additionally, a low reference signal 250 set by the user may also be provided to the controller 230 for comparison with the input signal and/or the adjusted signal to provide a control signal 225 to the adjustor 240 to increase the volume or the low levels of the input signal when the levels of the input signal and/or the adjusted signal are below the low reference signal 250.

Alternatively, the input signal may be adjusted when its levels and/or levels of the adjusted signal are above the high reference signal 225 or below the low reference signal 250 by a predetermined amount, which may be the same or different for the high and low references 225, 250. For example, the predetermined amount or a threshold of 25% may be set by the user for the high and 20% for the low, so that the sound level of input signal 215 is attenuated or limited if either or both sound levels of the input signal 215 and the adjusted signal 245 are 25% more than the high reference signal 225; or the sound level or the lows of input signal 215 are increased if either or both sound levels of the input signal 215 and the adjusted signal 245 are 20% below than the low reference signal 250. Various modifications may also be used, such as basing the adjustment on the difference in sound levels between current and past frames or program segments, where a predetermined amount set by the user triggers adjustment of the input signal. By analogy to the previous example, a 25% increase in sound levels of the current frame or segment with respect to the past or previous frame would trigger lowering, or limiting the highs of the current frame sound levels; while a 20% decrease in sound levels of the current frame with respect to the previous frame would trigger increasing the volume or the lows of current frame.

The controller 230 may be turned off by an on/off signal 260 thus preventing generation of the control signal 235, to effectively turning off the signal processing or volume control system 200. Thus the user can enjoy the loud noises associated with action scenes, or listen to music with all its highs and lows, as it is supposed to sound: without attenuating the level or high notes of an opera singer for example.

The present invention provides a versatile, responsive and accurate system to continuously and automatically keep constant sound levels during the same program, by continuously and automatically monitoring both the input and adjusted signals, and comparing them to threshold(s) set by the user, or determined such as by storing the current level value or measuring it using a detector when the user activates the system.

The methods of the present invention are particularly suited to be carried out by a computer software program, such computer software program preferably containing modules corresponding to the individual steps of the methods. Such software can of course be embodied in a computer-readable medium, such as an integrated chip, a peripheral device or memory, or other memory coupled to a processor, which may be a dedicated processor for performing in accordance with the present invention or may be a general-purpose processor wherein only one of many functions operates for performing in accordance with the present invention. The processor may operate utilizing a program portion, multiple program segments, or may be a hardware device utilizing a dedicated or multi-purpose integrated circuit. Each of the above systems utilized for identifying the presence and identity of the user may be utilized in conjunction with further systems.

Finally, the above-discussion is intended to be merely illustrative of the present invention and should not be construed as limiting the appended claims to any particular embodiment or group of embodiments. Thus, while the present invention has been described in particular detail with reference to specific exemplary embodiments thereof, it should also be appreciated that numerous modifications and changes may be made thereto without departing from the broader and intended spirit and scope of the invention as set forth in the claims that follow. The specification and drawings are accordingly to be regarded in an illustrative manner and are not intended to limit the scope of the appended claims.

In interpreting the appended claims, it should be understood that:

a) the word “comprising” does not exclude the presence of other elements or acts than those listed in a given claim;

b) the word “a” or “an” preceding an element does not exclude the presence of a plurality of such elements;

c) any reference signs in the claims do not limit their scope;

d) several “means” may be represented by the same item or hardware or software implemented structure or function; and

e) each of the disclosed elements may be comprised of hardware portions (e.g., discrete electronic circuitry), software portions (e.g., computer programming), or any combination thereof.

1. A signal processing system (200) comprising:
a source (210) configured to output a signal;
a controller (230) configured to output a control signal to change levels of said signal; and
an adjustor (240) configured to change levels of said signal to form an adjusted signal in response to said control signal;
wherein said controller (230) forms said control signal in response to said signal, said adjusted signal and a reference signal.

2. The signal processing system (200) of claim 1, wherein said controller (230) is configured to receive a further signal to activate or deactivate said controller (230).

3. The signal processing system (200) of claim 1, wherein said controller (230) is configured to compare said signal and said adjusted signal with said reference signal in order to form said control signal.

4. The signal processing system (200) of claim 1, wherein said controller (230) is configured to output said control signal to lower a level of said signal when at least one of said signal and said adjusted signal is greater than said reference signal.

5. The signal processing system (200) of claim 1, wherein said controller (230) is configured to output said control signal to lower a level of said signal when at least one of said signal and said adjusted signal is greater than said reference signal by a predetermined amount.

6. The signal processing system (200) of claim 1, wherein said controller (230) is configured to output said control signal to increase a level of said signal when at least one of said signal and said adjusted signal is less than said reference signal by a predetermined amount.

7. The signal processing system (200) of claim 1, wherein said controller (230) is configured to output said control signal to change a level of said signal when at least one of said signal and said adjusted signal is different from said reference signal by a predetermined amount.

8. The signal processing system (200) of claim 1, wherein said controller (230) is configured to output said control signal to lower a level of said signal when both said signal and said adjusted signal are greater than said reference signal.

9. The signal processing system (200) of claim 1, wherein said controller (230) is configured to output said control signal to increase a level of said signal when both said signal and said adjusted signal are less than said reference signal.

10. The signal processing system (200) of claim 1, wherein said controller (230) is configured to output said control signal to change a level of said signal when both said signal and said adjusted signal are different than said reference signal.

11. The signal processing system (200) of claim 1, wherein said reference signal is set by a user.

12. The signal processing system of claim 1, wherein said reference signal is a level of sound set by a user or measured by a detector.

13. A device (100) including an automatic volume control system (200), said automatic volume control system (200) comprising:
a controller (230) configured to output a control signal to change levels of an input signal; and
an adjustor (240) configured to change levels of said input signal to form an adjusted signal in response to said control signal;
wherein said controller (230) forms said control signal in response to said input signal, said adjusted signal and a reference signal; said adjustor limiting a level of said adjusted signal when levels of said input signal and/or said adjusted signal exceed said reference signal.

14. The device (100) of claim 13, wherein said controller (230) is configured to receive a further signal to activate or deactivate said controller.

15. The device (100) of claim 13, wherein said controller (230) is configured to compare said input signal and said adjusted signal to said reference signal in order to form said control signal.

16. The device (100) of claim 13, wherein said controller (230) is configured to output said control signal to change a level of said input signal when at least one of said input signal and said adjusted signal is different from said reference signal by a predetermined amount.

17. The device (100) of claim 13, wherein said controller (230) is configured to output said control signal to change a level of said input signal when both said input signal and said adjusted signal are different than said reference signal.

18. A method of maintaining a level of an input signal comprising:
providing said input signal to a controller (230) and a level adjuster (240);
forming a control signal (235) by a said controller (230) to change levels of said input signal; and
adjusting said input signal by said level adjuster in response said control signal to from an adjusted signal (245);
wherein said controller (230) forms said control signal (235) in response to said input signal, said adjusted signal and a reference signal.

19. A method of claim 18, wherein said adjusting act limits levels of said input signal by said level adjustor when levels of said input signal and/or levels said adjusted signal exceed said reference signal.

20. A system (200) for maintaining a level of an input signal comprising:
control means (230) for forming a control signal (235) to change levels of said input signal; and
adjusting means (240) for adjusting said input signal in response said control signal (235) to from an adjusted signal (245);
wherein said control means (230) forms said control signal (235) in response to said input signal, said adjusted signal and a reference signal.
